(19) United States
(12) Patent Application Publication
(10) Pub. No.: US 2016/0286644 A1
(43) Pub. Date: Sep. 29, 2016

(54) METAL SUBSTRATE WITH INSULATED VIAS

(71) Applicants: Cambridge Nanotherm Limited, Haverhill (GB); Rogers Corporation, Rogers, CT (US)

(72) Inventors: Pavel SHASHKOV, Linton (GB); Sergey USOV, Cambridge (GB); Steven CURTIS, London (GB); Brett W. KILHENNY, Mystic, CT (US)

(21) Appl. No.: 15/154,198

(22) Filed: May 13, 2016

Related U.S. Application Data
(63) Continuation of application No. PCT/GB2014/053074, filed on Oct. 13, 2014.
Application No. PCT/GB2014/053074 is a continuation-in-part of application No. 14/522,758, filed on Oct. 24, 2014.
(60) Provisional application No. 61/895,126, filed on Oct. 24, 2013.

(30) Foreign Application Priority Data
Nov. 15, 2013 (GB) 1320180.1

(51) Int. Cl. H05K 1/11; H05K 3/40; H05K 1/09; H05K 1/03; H05K 1/05; H05K 1/02

(52) U.S. Cl. CPC H05K 1/115; H05K 1/053; H05K 1/0206; H05K 1/09; H05K 1/0313; H05K 3/4038; H05K 1/0298; H05K 2201/05; H05K 2203/0315; H05K 2201/0116; H05K 2203/1147; H05K 2201/10128; H05K 2201/10037; H05K 2201/10121; H05K 2201/10098; H05K 2201/10219

(57) ABSTRACT

A metal substrate with insulated vias (MSIV) has a metallic layer with through-holes defined through a thickness of the layer, a dielectric layer formed on part of the surface of the metallic layer and extending to cover internal walls of the through-hole, a conductive material extending through the insulated through-hole to form an insulated via, and an electrical circuit formed on a portion of the dielectric layer in thermal and/or electrical contact with the conductive via. The dielectric layer is a dielectric nanoceramic layer having an equiaxed crystalline structure with an average grain size of 500 nanometres or less, a thickness of between 0.1 and 100 micrometres, a dielectric strength of greater than 20 KV mm⁻¹, and a thermal conductivity of greater than 3 W/mK. Such a MSIV can be used as an electronic substrate to support devices such as power, microwave, optoelectronic, solid-state lighting and thermoelectric devices.

### CROSS-REFERENCE TO RELATED APPLICATIONS

The present application is a by-pass continuation of International Application No. PCT/GB2014/053074 filed on Oct. 13, 2014, which claims the benefit of priority of British Application No. 1320180.1 filed in Great Britain on Nov. 15, 2013; and the present application also is a continuation-in-part of U.S. application Ser. No. 14/522,758 filed on Oct. 24, 2014, which claims the benefit of priority of U.S. Provisional Application No. 61/895,126 filed on Oct. 24, 2013. The entire disclosures of these earlier applications are incorporated by reference herein.

The invention relates to metal substrates comprising a metallic layer and a conductive via extending through the metallic layer. The conductive via is electrically insulated from the metal substrate and provides electrical and/or thermal connection to opposite sides of the metallic layer. Such metal substrates may be used as substrates to support power, microwave, optoelectronic, solid-state lighting and thermoelectric devices.

### BACKGROUND

Electronic substrates with vias are typically used to provide a multi-layered electronic board with electrical and/or thermal connection between surface areas of different layers. Conductive vias may be used to arrange power and signal supply and may act to remove heat from electrical components.

The most common base-layer materials for multi-layered boards are aluminium oxide (Al₂O₃) or aluminium nitride (AlN) ceramic layers, and FR4 epoxy resin board layers. Vias in such base-layer materials are formed by drilling through-holes, and then filling these through-holes with conductive material or metal plating. There are limitations in the use of each of these common base materials, however. For example, FR4 as a base material has very low thermal conductivity (about 0.1 W/mK) and it cannot be used for applications requiring high heat transfer.

Al₂O₃ has higher thermal conductivity than FR4 (about 20-30 W/mK), and is a currently preferred base-layer material for manufacture of electronic substrates with vias. AlN is used for the most thermally demanding applications as it has even higher thermal conductivity (about 140-180 W/mK). AlN is a significantly more expensive material than FR4 or Al₂O₃ and that limits its applications. Both Al₂O₃ and AlN (and other ceramic layers) suffer from an inherent brittleness. This brittleness prevents the formation of very thin base-layers of ceramic (it is difficult to form layers that are thinner than 100 micrometres) and limits the surface area of the ceramic base-layers to a few dozens of square inches.

The use of metals as a base-layer is beneficial for electronic substrate applications as metals have high thermal conductivity and high toughness. Electronic substrates formed using metallic layers (which may be termed metal substrates) do not have the same dimensional limitations as those formed with ceramic layers, and can be formed to be as thin as 10 micrometres. One of the most common metals used as a metallic layer in a metal substrate is aluminium (Al). Aluminium has a thermal conductivity of about 150-200 W/mK; similar to that of AlN substrates, but the material is significantly cheaper. The formation of multi-layered boards using metallic base-layers requires the formation of conductive vias through the metallic layers. The conductive cores of the vias must be electrically insulated from the base-layer metal. This is achieved by building metal substrates with insulated vias (MSIV).

There are a number of difficulties in providing electrical insulation between the vias of conducting material and a metallic base-layer of a MSIV. The standard process for realising a double-sided MSIV is typically as follows:

Firstly copper (Cu) layers are bonded to each side of a metallic layer using a dielectric film. The resulting panel (which consists of the metallic layer, two dielectric film layers and two copper layers) is then drilled to provide a through-hole extending through the panel. This through-hole exposes the material of the metallic layer, which means that the through-holes need to be plugged with an electrically insulating material before a conductive via can be formed. Once plugged, a smaller drill is used to drill through the electrically insulating plugging material. This second-through-hole can then be filled with a conducting material to create an electrically conducting via extending from one side of the metallic layer to the other. Electrical connection may be made using a wet chemical seed layer and plating processes, or by using electrically conductive via filling materials, or, using a combination of the above.

It can be seen that the process of via formation in a MSIV involves many steps and, therefore, a high degree of complexity. The main drawback, however, is the risk of electrical breakdown at the edge of the via hole where the dielectric provided by the electrically insulating hole-plug is minimal.

Attempts have been made to form MSIVs from pre-drilled Al panels that are then anodised to provide a dielectric layer on the surface and on inner walls of the through-holes. Such MSIVs did not find industrial application because anodic layers cannot provide sufficiently consistent and reliable electric insulation. This problem with anodised dielectric layers is due to porosity on the anodised layers and cracks at the through-hole edges caused by the inherent structure of anodised layers. Anodised dielectric layers also crack under thermal cycling, both on the flat surface of Al layers and within the through-holes.

### SUMMARY OF THE INVENTION

The invention provides, a metal substrate with insulated vias (MSIV) and a method of forming a MSIV as defined in the appended independent claims, to which reference should now be made. Preferred or advantageous features of the invention are set out in various dependent sub-claims.

Thus, in a first aspect a metal substrate with insulated vias (MSIV) may comprise

a metallic layer having a through-hole defined through a thickness of the metallic layer between a first surface and a second surface of the metallic layer,
a dielectric layer formed at least in part by oxidation of the metallic layer, the dielectric layer formed as a continuous layer on at least one of the first and second surface of the metallic layer, or on both the first and second surface of the metallic layer, and on internal walls of the through-hole,
a conductive metallic via extending through the through-hole defined in the metallic layer, the conductive metallic via being electrically insulated from the metallic layer by the dielectric layer, and
an electrical circuit formed on a portion of the dielectric layer, the electrical circuit being in electrical and/or thermal contact with the conductive metallic via. The dielectric layer is a dielectric nanoceramic layer having an equiaxed crystalline structure with an average grain size of 500 nanometres or less, a thickness of between 0.1 and 100 micrometres, a dielectric strength of greater than 20 KV mm⁻¹, and a thermal conductivity of greater than 3 W/mK.

As used herein, a metallic layer is a layer that has length and width dimensions that are substantially greater than its thickness dimension. A metallic layer may be referred to as a metallic base-layer or a metallic sheet. Preferably, the metallic layer has a thickness of between 5 micrometres and 5000 micrometres, preferably between 10 micrometres and 2000 micrometres, or between 20 micrometres and 500 micrometres. In some embodiments the metallic layer may be a flexible structure such as a metallic foil. In some embodiments the metallic layer may be a rigid structure, for example a metallic plate. In some embodiments the metallic layer may be a shaped structure or component.

The metallic layer may have a plurality of through-holes defined through the thickness thereof, internal walls of each of the plurality of through-holes being coated with a portion of the dielectric nanoceramic layer. Multiple through-holes may be defined in patterns at different portions of the metallic layer to optimise thermal and/or electrical conductivity for particular purposes.

As used herein, the term metal substrate refers to a type of electronic substrate formed from a metallic layer or sheet that is insulated with a dielectric layer on one or both sides of the metallic layer.

The dielectric nanoceramic layer is formed at least in part by oxidation of the metallic layer and may also be referred to herein as a dielectric coating or a nanoceramic layer or a nanoceramic coating.

A MSIV according to any aspect of the invention comprises conductive vias formed through, but electrically insulated from, the metallic layer. Through-holes are formed through the metallic layer, for example by mechanical or laser drilling or by punching of the metallic layer. The dielectric nanoceramic layer is then formed, and this layer extends continuously across at least a portion of a surface of the metallic layer and also covers the internal walls of the or each through-hole to provide an insulated through-hole or holes. A conductive material such as a metal can then be formed within the insulated through-hole to create a conductive via. Through-holes may be formed with diameters as small as 20 micrometres. The upper dimension may be any diameter, but many through-holes will have diameters within the range of 20 micrometres to 2000 micrometres. Advantageously, a dielectric nanoceramic coating may be formed on inner walls of through-holes having aspect ratios as high as 10 or 15 or 20, or higher. The aspect ratio is defined as the depth of the through-hole divided by the diameter of the through-hole. Preferably, the aspect ratio of the through-hole is between 0.1 and 20.

The ability to form multiple through-holes, and therefore multiple vias, in close proximity to one another may be a particularly advantageous feature. Prior art MSIVs do not have closely spaced vias due to manufacturing problems. Thus it may be advantageous that the metallic layer comprises a plurality of through-holes of between 20 and 300 micrometres in diameter, or between 50 and 200 micrometres in diameter, in which the spacing between through-holes is of the same order as the diameter of the through holes, for example between 20 and 300 micrometres or between 50 and 200 micrometres.

The coating has a crystalline structure having an average grain size of less than 500 nanometres. Such a nanocrystalline structure provides a uniform dense layer on the surface of the metallic layer, including the edges and internal surfaces of the through-hole(s). Advantageously, the average grain size may be 250 nanometres or less, or 100 nanometres or less.

The microstructure of the dielectric nanoceramic consists substantially of equiaxed grains. That is the grains making up the nanoceramic have x, y, and z axes of approximately the same length. Equiaxed grains have a greater number of operational slip-planes, and the nanoceramic has higher strength and ductility than would be the case were the grain structure to be anisotropic. The small grain size and the substantially equiaxed grain structure are important parameters that allow uniform coverage of the dielectric layer on complex shapes such as through-holes. Thanks to the nanoscale grain size and equiaxed structure, the dielectric nanoceramic layer may be uniformly applied to cover internal surfaces of through-holes with internal diameters as low as 20 microns and an aspect ratio (which is equal to thickness of a substrate divided by the diameter size of a hole) of up to 20.

The thickness of the dielectric nanoceramic layer is between 0.1 and 100 micrometres. In this thickness range the substantially equiaxed nanoceramic layer has a high dielectric strength of greater than 20 KV/mm and high thermal conductivity of greater than 3 W/mK. These values are favourable for many electronic substrate applications. In some embodiments the thickness of the dielectric nanoceramic layer may be between 1 micrometre and 50 micrometres, for example between 5 micrometres and 40 micrometres, or between 10 micrometres and 30 micrometres.

Advantageously, the dielectric layer may be formed as a continuous layer on both the first and second surface of the metallic layer and on the internal walls of the through-hole. First and second electrical circuits may then be formed on portions of the dielectric layer formed on both first and second surfaces of the metallic layer respectively, the first and second electrical circuits being electrically and/or thermally connected by the conductive metallic via. In this way, a multi-layered structure may start to form in which electrical circuits at different levels are supported on a metal substrate and are connected by means of vias that are insulated from the metallic layer of the metal substrate.

The term metallic is used herein to describe broad classes of material. Thus, this term describes elemental metals such as pure aluminium, as well as alloys of one or more elements, and intermetallic compounds. Practically, the metal layers used to form MSIVs described herein are likely to be sheets of commercially available metallic compositions. Many metals may be suitable for use as a metallic layer on which the coating is formed. Suitable materials may include those metals classed as valve metals. A MSIV may be preferably formed using a metallic layer that is aluminium, magnesium, titanium, zirconium, tantalum, beryllium, or an alloy or intermetallic of any of these metals.

For electronic substrate applications, the dielectric strength of an insulating dielectric layer is of particular importance. The nanoceramic layer described herein may, advantageously, provide a dielectric strength of between 20 kV/mm and 100 kV/mm.

For electronic substrate applications, it is preferred that the thermal conductivity of a dielectric layer is high. An insulating dielectric layer or coating is required to provide electrical insulation between a working electronic component and a metallic layer supporting that component, and simultaneously conduct heat away from this component into the metallic layer. It may be advantageous, therefore, that the dielectric nanoceramic layer according to any aspect described herein has a thermal conductivity of greater than 3 W/mK, for example between 3 and 7 W/mK.

For some electronic substrate applications it may be preferred that the dielectric layer has a high dielectric constant. A high dielectric constant may be particularly preferred when the MSIV is intended to be used in RF or microwave applications. Preferably, the MSIV comprises a dielectric layer with a dielectric constant that is greater than 7, for example between 7.5 and 10.

Many physical properties of ceramic coatings formed on a metal substrate are dependent to some extent on the crystallite size or grain size of the ceramic coating. The nanoceramic layer described herein is a crystalline ceramic coating comprising equiaxed grains having an average diameter of less than 500 nanometres, particularly preferably less than 100 nanometres, for example about 50 nanometres or 40 nanometres or 30 nanometres. Grains may be alternatively referred to as crystals or crystallites. The term grain size refers to the distance across the average dimension of a grain or crystal in the material, for example the dielectric layer. Thus, a MSIV comprises a layer or coating that may be described as a nanostructured layer, or a nanoceramic layer, as it has physical features that have a size or dimensions on the nanometre scale. Fine grain sizes may improve structural homogeneity and properties such as ability to form uniform layers of dielectric inside vias and on their borders. Fine grain sizes may also increase thermal conductivity, dielectric strength and dielectric constant of a ceramic material. A smoother surface profile may also be developed as a result of the fine grain size.

In some embodiments it may be advantageous if the MSIV is flexible. Flexibility of the MSIV may be defined by reference to a bend radius. Bend radius is a standard measurement of flexibility used to characterise materials in the form of wires, cables, and sheets. To measure the bend radius, a sheet is typically bent around rods or cylinders of decreasing diameter to determine the minimum curvature to which the sheet may be bent without damage. A MSIV is likely to be in the form of a sheet of material. As used herein, bend radius refers to a radius that a MSIV can be bent to repeatedly without damaging its properties. Minimum bend radius is the minimum curvature to which a MSIV can be bent without damaging its properties.

The minimum bend radius of a MSIV depends to some degree on the total thickness of the MSIV. Where the FES is of a high thickness (for example 2 mm) the minimum band radius may be high. For example the minimum bend radius is preferably lower than 25 cm, particularly preferably lower than 15 cm, or lower than 10 cm. In some embodiments, a MSIV may have a total thickness of lower than 2 mm and the flexibility of the MSIV may be high. It may be preferred that the minimum bend radius of the MSIV is lower than 20 mm, for example lower than 10 mm, or lower than 5 mm, for example between 2 mm and 5 mm.

A preferred embodiment of a MSIV may comprise a metallic layer, a dielectric nanoceramic layer formed at least in part by oxidation of a surface of the metallic layer, and an electrical circuit formed on a surface of the dielectric layer, in which the dielectric nanoceramic layer has a crystalline structure consisting of grains having an average grain size 100 nanometres or less, a thickness of between 1 micrometre and 50 micrometres, a dielectric strength of greater than 20 KV mm⁻¹, and a thermal conductivity of greater than 3 W/mK, the metallic layer defining through-holes, walls of the through-holes being coated by dielectric nanoceramic material that is of the same composition as, and continuous with, the dielectric nanoceramic layer.

A layer or coating formed on a metallic layer by an anodising process tends to be highly porous. Anodised coatings also usually have an amorphous structure (i.e. anodised coatings are rarely crystalline) and an open, column-like structure. The regular column-like structure of a typical anodised coating may render the coating susceptible to the formation of cracks, particularly after thermal cycling or bending of the coating. The susceptibility to crack formation limits the application of anodised coatings in electronic substrates.

To form a MSIV according to any aspect of the invention a nanoceramic layer possessing the desired properties is formed on at least a part of metallic layer. The metallic layer has pre-drilled vias. A nanoceramic layer may be formed using any suitable method. A preferred method of forming a nanoceramic layer on a metallic layer comprises the steps of positioning the metallic layer in an electrolysis chamber containing an aqueous electrolyte and at least two electrodes. At least part of the surface of the metallic layer on which it is desired to form a crystalline nanoceramic coating and a portion of the electrodes are in contact with the aqueous electrolyte.

By applying a sequence of electrical voltage pulses of alternating polarity between the part and electrodes in which positive and negative pulses are independently potentiostatically or galvanostatically controlled, it is possible to apply pulses of high voltage without inducing substantial levels of micro-discharge. By minimising or avoiding micro-discharge events during the formation of the nanoceramic coating, it may be possible to control coating parameters such as the surface roughness and the magnitude of the coating porosity. Thus, by controlling this process a nanoceramic layer may be formed having an average pore size lower than 500 nanometres, if desired.

Micro-discharge may also be termed microspark discharge or microarcing. The presence of micro-discharge is an essential feature of a PEO coating process, but produces ceramic layers that are inherently not suitable for use in a MSIV. Thus, it is preferred that the nanoceramic coating is produced using a spark-less process.

It may be advantageous for the positive and negative voltage pulses to be shaped to avoid the development of current spikes during each voltage pulse. Current spikes are associated with the breakdown of the coating and with micro-discharge. By shaping the voltage pulses to avoid current spikes, micro-discharge may be reduced significantly or eliminated. As stated above, micro-discharge has a deleterious effect on a number of coating properties, for example on the average pore size of the layer and, as a consequence, on the dielectric strength of the layer.

It may be particularly advantageous if the shape of one or both of the positive and negative voltage pulses is substantially trapezoidal in shape.

The conversion of material in the metallic layer to form a nanoceramic layer occurs during the positive voltage pulses in which the metallic layer is anodically biased with respect to the electrode. The nanoceramic layer is formed as oxygen containing species in the aqueous electrolyte react with the metallic material itself. Over successive positive voltage pulses the nanoceramic layer increases in thickness. As the layer increases in thickness the electrical resistance of the layer increases and less current flows for the applied voltage. Thus, while it is preferred that the peak voltage of each of the positive voltage pulses is constant over the predetermined period, the current flow with each successive voltage pulse may decrease over the predetermined period.

As the nanoceramic layer grows in thickness, the resistance of the layer increases and, therefore, the current passing through the layer during each successive negative voltage pulse causes resistive heating of the layer. This resistive heating during negative voltage pulses may contribute to increased levels of diffusion in the layer, and may therefore assist the processes of crystallisation and grain formation within the developing layer.

By controlling the formation of the nanoceramic coating in this manner, preferably in which micro-discharge is substantially avoided, a dense coating may be formed having crystallites or grain size of extremely fine scale. Preferably, the grain size of the nanoceramic coating formed is less than 200 nanometres, particularly preferably less than 100 nanometres, for example less than 50 nanometres.

It may be advantageous if the nanoceramic layer is formed using an electrolysis process carried out in an electrolyte that is an alkaline aqueous solution, preferably an electrolyte having a pH of 9 or greater. Preferably, the electrolyte has an electrical conductivity of greater than 1 mS cm⁻¹. Suitable electrolytes include alkaline metal hydroxides, particularly those comprising potassium hydroxide or sodium hydroxide.

It may be particularly advantageous if the electrolyte is colloidal and comprises solid particles dispersed in an aqueous phase. Particularly preferably the electrolyte comprises a proportion of solid particles having a particle size of less than 100 nanometres.

Particle size refers to the length of the largest dimension of the particle.

An electric field generated during the applied voltage pulses causes electrostatically charged solid particles dispersed in the aqueous phase to be transported towards the surface of the metallic layer on which the non-metallic nanoceramic coating is growing. As the solid particles come into contact with the growing nanoceramic coating they may react with, and become incorporated into, the coating. Thus, where a colloidal electrolyte is used the nanoceramic coating may comprise both nanoceramic material formed by oxidation of a portion of the surface of the metallic layer and colloidal particles derived from the electrolyte.

The nanoceramic coating forming on the metallic layer is generated during the positive, anodic, voltage pulses. In order for the nanoceramic coating to grow a connection needs to be maintained between the metallic layer and the electrolyte. The growing nanoceramic coating is not fully dense, but has a degree of porosity. The connection between the metallic layer material and the electrolyte is maintained via this porosity. Where the electrolyte is colloidal and comprises solid particles the porosity that is inherent in the formation of the nanoceramic coating may be substantially modified. Non-metallic solid particles dispersed in the aqueous phase may migrate under the electric field into pores of the growing coating. Once within the pores the solid particles may react, for example by sintering processes, with both the coating and with other solid particles that have migrated into the pores. In this way the dimensions of the pores are substantially reduced and the porosity of the coating is altered develops as nanoporosity. For example, the maximum dimensions of pores in the coating may be reduced from 1 or more micrometers across to less than 400 nanometres across or less than 300 nanometres across.

By reducing the porosity the density of the nanoceramic coating is increased. Furthermore, the reduction in the dimensions of the porosity through the coating may substantially increase the dielectric strength and thermal conductivity of the coating.

An apparatus suitable for forming a dielectric nanoceramic coating on the surface of a metallic layer may comprise an electrolysis chamber for containing an aqueous electrolyte, at least two electrodes locatable within the electrolysis chamber, and a power supply capable of applying a sequence of voltage pulses of alternative polarity between the metallic layer and the electrode.

It may be particularly advantageous that the apparatus further comprises a colloidal electrolyte comprising solid particles dispersed in an aqueous phase. The solid particles dispersed in such an electrolyte may become incorporated into the nanoceramic coating generated using the apparatus.

The above described exemplary technique of forming a nanoceramic coating provides uniformity of the dielectric coating inside through-hole vias, as long as the electrical field provided in the electrolytic tank is applied from both surfaces of the metallic layer. Uniformity is achieved thanks to a thickness levelling effect, which means that coated areas with higher nanoceramic thickness have higher electrical resistance, which leads to preferential nanoceramic growth in areas with lower nanoceramic thickness. This self-levelling mechanism may explain the ability to provide consistent thickness and quality of nanoceramics on edges and corners.

For certain applications, it may be desirable to fill any pores that exist in the nanoceramic coating. Thus, a MSIV according to any aspect of the invention may comprise a nanoceramic coating that has been sealed or impregnated by a suitable organic or inorganic material to fill any pores in the coating. A suitable sealing material may be, for example, a resin, a fluoropolymer, a polyimide, a polyester, a water glass, acrylic or a sol-gel material. This list of suitable sealing materials is not exhaustive and the skilled person would be able to identify other suitable materials. Sealing materials may be applied to the coating by a number of known methods, for example by dipping, spraying, vacuum impregnation, and by PVD and CVD deposition techniques.

A MSIV according to any aspect of the invention comprises an electrical circuit or circuits built on the surface of the nanoceramic layer. Electrical circuits may be provided by any conventional techniques such as screen printing, conductive ink printing, electroless metallisation, galvanic metallisation, adhesive bonding of metal foil, bonding of pre-fabricated flex circuits, metal sputtering, chemical vapour deposition (CVD) and physical vapour deposition (PVD) metallisation.

A MSIV according to any aspect of the invention comprises a conductive via located within the insulated through-holes. The conductive via comprises a conductive material, such as a metal, that passes through the insulated through-holes, thereby forming insulated vias. Incorporation of the conductive material into the through-holes may be achieved by conventional techniques such as filling via with conductive material by screen printing, electroless and galvanic metallisation, chemical vapour deposition (CVD) and physical vapour deposition (PVD). Building insulated vias with conductive cores can be achieved by a combination of above techniques, such as building a metal seed layer by an electroless process, followed by galvanic build up of conductive via material.

A preferred embodiment of a MSIV that is particularly suitable for high temperature application may comprise a metallic layer having a nanoceramic coating formed on the metallic layer and electrical circuit built with completely with non-organic materials such as metals, for example by metal sputtering followed by electroless or galvanic metallisation. Such MSIVs have fully non-organic composition and can operate at temperatures above 200° C. They are not affected by thermal degradation inherent to plastic materials. Non-organic MSIVs may be of particular interest when used as substrates for devices used for example in semiconductor packaging, high temperature electronics, concentrated photovoltaics, thermoelectric energy harvesting, high brightness LEDs or sensors working at elevated ambient temperatures. These applications often require a through-hole via connection from top-to-bottom side of the board.

A further aspect may provide a method of forming a metal substrate with insulated vias (MSIV) as described above, comprising the steps of:

providing a metallic layer,
defining through-holes through a thickness of the metallic layer between a first surface and a second surface of the metallic layer,
forming a dielectric layer on at least one of the first surface and the second surface of the metallic layer and on internal walls of the through-hole, the dielectric layer being formed at least in part by oxidation of the metallic layer,
filling the through-hole with conductive material to form a conductive via, and forming an electrical circuit on a portion of the dielectric layer, the electrical circuit being in electrical and/or thermal contact with the conductive via.

A further aspect may provide a device incorporating or mounted onto an MSIV according to any aspect above. A MSIV according to the invention has superior dielectric and thermal conductivity properties compared to prior art MSIVs, and devices mounted upon one may operate more efficiently due to the improved thermal transfer from components of the device through the MSIV. Such thermal transfer may be achieved by a combination of improved dielectric strength of the coating on the MSIV, which allows the coating to be thinner while providing electrical insulation, and an improved thermal conductivity of the material.

For certain applications, an MSIV having a multilayered structure may prove advantageous. For example, an MSIV may be formed according to any aspect or embodiment described above, and this MSIV may then form the base of a multilayered MSIV. That is, further MSIVs may be applied to a surface of the MSIV to form a multi-layered structure.

### BRIEF DESCRIPTION OF THE DRAWINGS

Preferred embodiments of the invention are described below with reference to the drawings, of which:

FIG. 1 is a side cross-sectional view of a MSIV embodying the invention, which comprises a metallic sheet with insulated vias, the insulation of which is provided by a dielectric nanoceramic layer. Electrical circuits built on both sides of the insulated metallic layer are connected through conductive vias.

FIG. 2 is a schematic illustration of an electrolytic apparatus suitable for building a nanoceramic dielectric coating on a metallic layer with through-hole vias.

FIGS. 3A-3C are schematic diagrams illustrating building of a MSIV using a thick film metallisation technique.

FIGS. 4A-4F are schematic diagrams illustrating building of a MSIV using an adhesively bonded copper technique.

FIGS. 5A-5F are schematic diagrams illustrating building of a MSIV using direct metallisation through sputtering of metal seed layer and subsequent galvanic pattern plating.

FIGS. 6A and 6B are SEM images of a cross-section of a metal substrate with insulated through-hole vias before and after metallisation, respectively.

FIGS. 7A and 7B are SEM images of a cross-section of insulated metal substrates with nanoceramic and anodised dielectric layers, respectively.

FIG. 8 is an X-ray diffraction (XRD) pattern of a nanoceramic coating formed on an aluminium alloy.

### PREFERRED EMBODIMENTS OF THE INVENTION

FIG. 1 provides a schematic side view of a metal substrate with insulated vias (MSIV) embodying the invention, which comprises a metallic layer or sheet 11 insulated on upper and lower surfaces by a dielectric nanoceramic layer 12. The MSIV includes electrical circuits 13, 14 built on surfaces of the nanoceramic layer 12 on opposite sides of the metallic sheet 11. The dielectric nanoceramic layer provides electrical insulation of the surface of the conductive through-hole vias 15 which interconnect areas of electrical circuits 13 and 14.

The metallic sheet may have a thickness of anywhere between 10 and 30,000 micrometers. The thickness is determined by the range of requirements such as thermal capacity, thermal resistance, mechanical strength. The metallic layer should be formed from a metal which can be treated by electrochemical conversion technology to form a nano-crystalline oxide layer on the surface of the metallic layer. Examples of such metals include aluminium, magnesium, titanium, zirconium, tantalum, beryllium, or an alloy or intermetallic of any of these metals.

The nanoceramic coating 12 is applied using proprietary technology of electrochemical conversion of metal to oxide in colloidal electrolyte as described in GB Patent GB2497063, the contents of which is incorporated herein by reference. The thickness of the nanoceramic layer may be varied from 0.1 and 100 micrometers, and this thickness is determined by the electric insulation requirements of the MSIV, such as breakdown voltage.

Electrical circuits 13 and 14 are built on the surface of the nanoceramic layer, on opposite sides of the MSIV. The electrical circuits are formed by a conventional method such as screen printing, conductive ink jet printing, electroless metallisation, galvanic metallisation, adhesive bonding of metal foil, bonding of pre-fabricated flex circuits, metal sputtering, chemical vapour deposition (CVD) and physical vapour deposition (PVD) metallisation, or a combination of such methods. Conductive cores of vias may be built within insulated through-holes using a printed Ag or printed Cu via fill material with high metal content, or by plating of Cu.

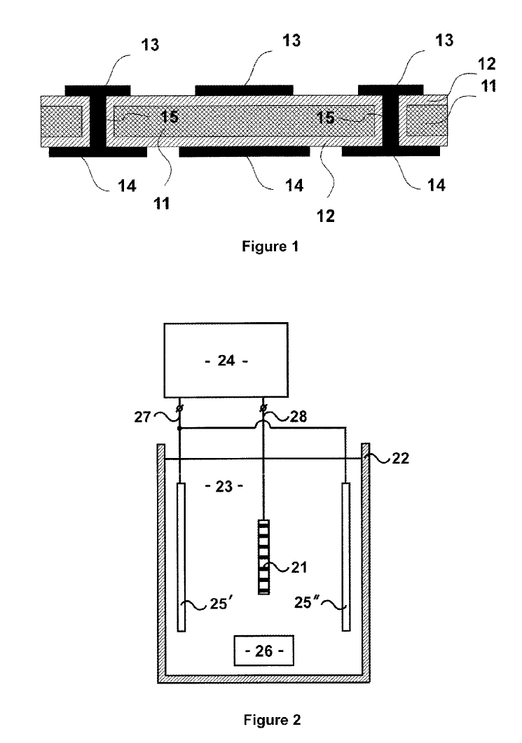

FIG. 2 illustrates a typical electrolytic apparatus suitable for use with a method of forming a nanoceramic dielectric layer on a metallic layer with pre-drilled through-holes 21. The apparatus comprises a chemically inert tank 22, for example a tank formed from a stainless steel alloy, which contains an electrolyte solution 23. The electrolyte solution 23 is an aqueous alkaline electrolyte solution, for example an aqueous solution of sodium hydroxide or potassium hydroxide, and has an electrical conductivity of greater than 1 mS cm⁻¹. The electrolyte may be a colloidal electrolyte comprising solid particles, with a proportion of those particles having a particle size lower than 100 nanometres.

A metallic layer or sheet 21 on which it is desired to form a non-metallic coating is electrically connected to a first output 27 of a pulse power supply 24. Electrodes 25′ and 25″ are connected to a second output 28 of the pulse power supply 24. The two electrodes 25′ and 25″ are disposed on either side of the metallic layer 21 in order to generate an even electric field over the surface of the metallic layer and inside through-holes defined through the metallic layer. Electrodes 25′, 25″ and the metallic layer 21 are immersed in the electrolyte solution 23 contained within the tank 22. The pulse power supply 24 is capable of supplying electrical pulses of alternating polarity in order to electrically bias the metallic layer 21 with respect to the electrodes 25′ and 25″.

It is noted that more than two electrodes may be coupled to an output of the pulse power supply 24 should this be desired. Likewise, more than one metallic layer may be simultaneously coupled to an output of the pulse power supply 4 so that more than one metallic layer may be coated at any one time.

The apparatus of FIG. 2 further comprises a heat exchanger 26 through which the electrolyte 23 is circulated. The heat exchanger 6 allows circulation of electrolyte 23 within the tank 22, and furthermore allows control of the temperature of the electrolyte.

### Example 1

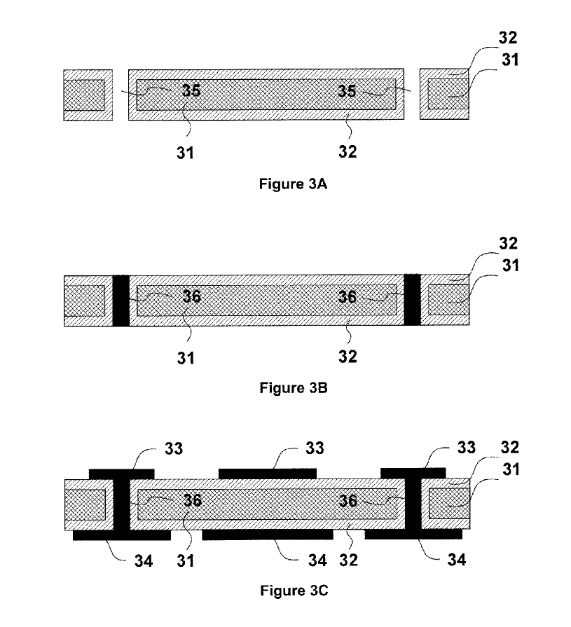

FIGS. 3A to 3C illustrate the steps involved in forming a specific embodiment of a MSIV using a thick film metallisation technique. Such MSIVs may be advantageously used, for example, for semiconductor packaging. For example, such MSIVs may be used as metal substrates for LED surface mount components.

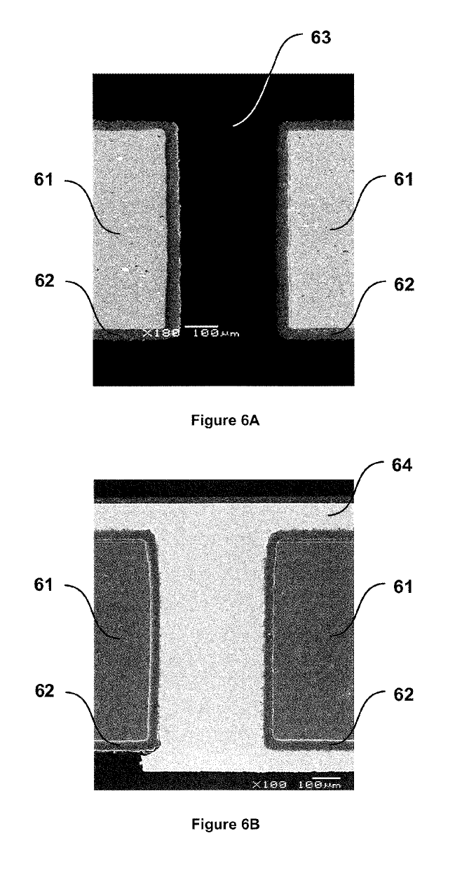

FIG. 3A illustrates a base metallic layer 31 which is 0.5 mm thick aluminium sheet (6061 grade) having through-holes 35 of 0.2 mm diameter defined through the sheet from a top surface to a bottom surface. The aluminium sheet is treated by the electrochemical process described above to create a nanoceramic dielectric coating 32 on both surfaces and on inside walls of the through-holes 35. A SEM cross section image of this insulated substrate is shown in FIG. 6. The dielectric nanoceramic layer 32 uniformly and continuously covers both flat surfaces and internal walls of the through-hole 35 without cracks or defects. The thickness of the dielectric layer is 20 microns, which provides electrical insulation corresponding of 1300 V DC.

Vias 36 are formed by filling the insulated through-hole with Ag via-fill material, as shown in FIG. 3B. Electric circuits 33 and 34 are then built on both sides of the metallic layer by screen printing with subsequent thermal or photonic curing (FIG. 3C). Areas of circuits on opposite sides of the metallic sheet are formed on the dielectric nanoceramic coating and are electrically and thermally connected by means of the conductive vias 36 that extend through, but are electrically insulated from, the metallic layer.

### Example 2

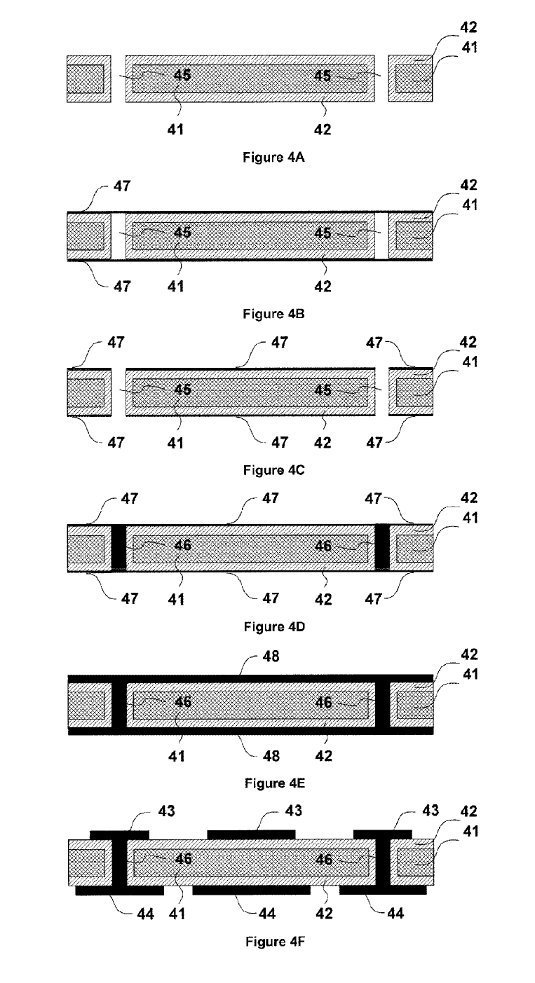

FIGS. 4A to 4F illustrate the steps involved in forming a specific embodiment of a MSIV using an adhesively bonded copper technique. Such MSIVs may be particularly preferred, for example, as substrates for power electronic application.

FIG. 4A illustrates a base metallic layer 41 which is 1 mm thick aluminium sheet (6082 grade) with through-holes 45 of 0.3 mm diameter. The aluminium sheet is treated by the electrochemical process described above to create a nanoceramic dielectric coating 42 on both surfaces and on inside walls of the through-holes 45. The thickness of the dielectric nanoceramic layer is 35 micrometres, which provides electrical insulation of 2000 V DC.

A 35 micrometre thick copper foil 47, primed with a 4 micrometre thickness of epoxy resin, is adhesively bonded to both sides of insulated sheet as shown in FIG. 4B. The copper foil is then etched away from the areas of the through-holes (FIG. 4C). A photoresist mask may be applied to prevent etching of copper foil from other areas of the metallic layer.

The through-holes are then filled with plateable Cu paste 46 to form conductive vias, as shown in FIG. 4D. Subsequently, a 70 micrometre thick layer of copper is applied galvanically on both sides of the metallic layer, thus bringing total thickness of the copper layer on each side of the metallic layer to 105 micrometers (FIG. 4E). Finally, electric circuits 43 and 44 are formed on both sides of the substrate by etching the copper layers through appropriately positioned photoresist mask, leaving a fully formed MSIV (FIG. 4F).

### Example 3

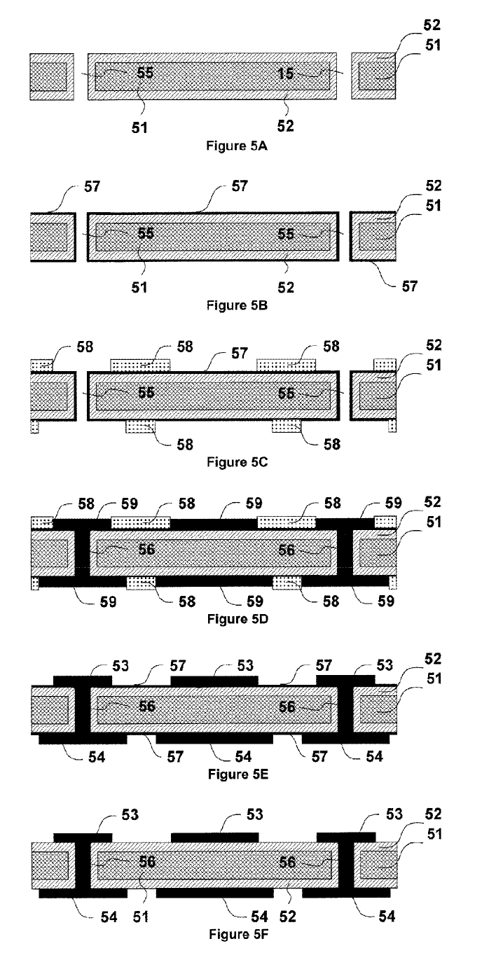

FIGS. 5A to 5F illustrate the steps involved in forming a specific embodiment of a MSIV using direct metallisation, by sputtering, of a TiCu seed layer and subsequent galvanic pattern plating. Such MSIVs may be used, for example, for semiconductor packaging. For example, such MSIVs may be advantageously used as metal substrates for high power LED die arrays.

FIG. 5A illustrates a base metallic layer 51 which is 0.5 mm thick aluminium sheet (Al 6061 grade) with through-holes of 0.15 mm diameter defined through the sheet from a top surface to a bottom surface. The aluminium sheet is treated by the electrochemical process described above to create a nanoceramic dielectric coating 52 on both surfaces and on inside walls of the through-holes 55. The dielectric nanoceramic layer uniformly and continuously covers both flat surfaces and surfaces inside the through-holes without cracks or defects. The thickness of the dielectric nanoceramic layer is 15 micrometres, which provides electrical insulation corresponding to 1000 V DC. A seed TiCu layer 57 is then applied to all surfaces of the dielectric layer, including surfaces inside the through-holes. The seed layer is applied using sputtering of TiCu (FIG. 5B). The seed layer is deposited to a thickness of 2 micrometres. Photoresist mask 58 is then applied to the seed layer (FIG. 5C) and the growing substrate is Galvanically plated with copper. Copper is plated to create a layer 70 micrometres thick 59 on both sides of the metallic layer (FIG. 5D). The plating process builds areas of conductive pads and tracks, and also completely fills the through-holes with copper thereby creating conductive vias 56. The photoresist is subsequently removed (FIG. 5E) and the seed layer is etched to complete the formation of circuits 53 and 54 on both sides of substrate (FIG. 5F).

FIGS. 6A and 6B are SEM images showing a cross-section of a metallic layer with a dielectric layer forming insulated through-holes, both before metallisation to form insulated vias (FIG. 6A) and after metallisation (FIG. 6B). The metallic layer is a 0.5 mm thick Al sheet 61 with a 20 micrometre nanoceramic coating 62 which provides electric insulation across all surfaces of the metallic layer 61 including the internal walls of through-holes 63 defined through the sheet. FIG. 6A demonstrates that the nanoceramic layer uniformly and consistently covers both flat surfaces of the metallic layer 61 and internal surfaces of the through-hole. FIG. 6B demonstrates that metallisation 64 completely fills the through-hole to form a conductive via, and covers required areas on both sides of the substrate with a 35 micrometre thick layer of Cu to create electrical circuits.

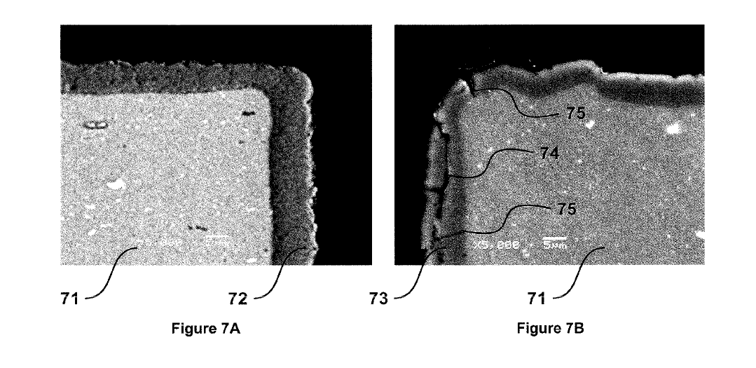

FIG. 7A is an SEM image of a cross-section of a through-hole that has been insulated using a nanoceramic coating as defined herein. By contrast, FIG. 7B is an SEM image of the same scale, showing an equivalent portion of a through-hole that has been insulated by anodisation of a metallic layer. FIG. 7A demonstrates a uniform dielectric layer 71, which has no physical defects and provides required electrical insulation. FIG. 7B, however, shows multiple defects in an anodised insulating layer 73 in the form of delamination 74 and cracks 75 that reach the base Al metallic layer 71. The anodised coating is not capable of providing required electrical insulation inside through-holes to allow formation of a metal substrate with insulated vias.

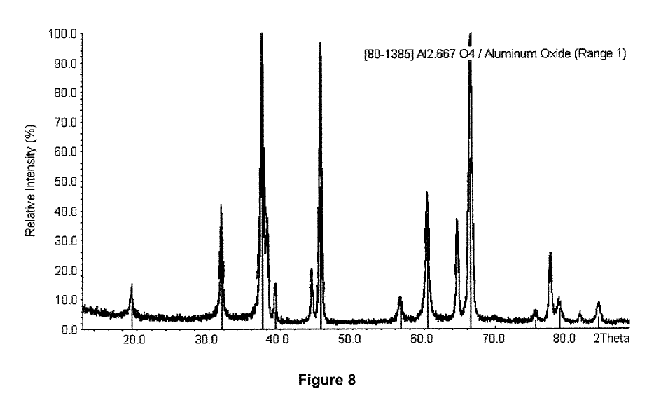

FIG. 8 is an X-ray diffraction (XRD) pattern of a nanoceramic coating formed on an aluminium alloy. An XRD analysis of the coating reveals that the composition of the coating was aluminium oxide and that the coating having mean crystalline grain size of 40 nm. Analysis of widening of diffraction peaks proves that crystallites are substantially equiaxed. The average crystalline size was calculated on the base of the XRD data according to the Scherrer equation (B. D. Cullity & S. R. Stock, Elements of X-Ray Diffraction, 3^{1d} Ed., Prentice-Hall Inc., 2001, p 167-171).

1: A metal substrate with insulated vias (MSIV), comprising:
a metallic layer having a through-hole defined through a thickness of the metallic layer between a first surface and a second surface of the metallic layer;
a dielectric layer formed at least in part by oxidation of the metallic layer, the dielectric layer being formed as a continuous layer on at least one of the first surface and the second surface of the metallic layer, and on internal walls of the through-hole;
a conductive metallic via extending through the through-hole defined in the metallic layer, the conductive metallic via being electrically insulated from the metallic layer by the dielectric layer; and
an electrical circuit formed on a portion of the dielectric layer, the electrical circuit being in electrical contact or thermal contact or both electrical and thermal contact with the conductive metallic via,
wherein the dielectric layer is a dielectric nanoceramic layer having an equiaxed crystalline structure with an average grain size of 500 nanometres or less, a thickness of between 0.1 and 100 micrometres, a dielectric strength of greater than 20 KV mm⁻¹, and a thermal conductivity of greater than 3 W/mK, and
wherein at least a portion of the dielectric nanoceramic layer is impregnated with organic or non-organic material.

2: A MSIV according to claim 1, wherein the dielectric nanoceramic layer includes grains having an average grain size of 100 nanometres or less.

3: A MSIV according to claim 1, wherein the dielectric nanoceramic layer has a thickness of between 1 micrometre and 50 micrometres.

4: A MSIV according to claim 1, wherein the metallic layer has a thickness of between 5 micrometres and 5000 micrometres.

5: A MSIV according to claim 1,
wherein the dielectric nanoceramic layer is formed as a continuous layer on both the first surface and the second surface of the metallic layer and on the internal walls of the through-hole, and
wherein first and second electrical circuits are formed on portions of the dielectric nanoceramic layer formed on both the first and second surfaces of the metallic layer,
respectively, the first and second electrical circuits being electrically connected or thermally connected or both electrically and thermally connected by the conductive metallic via.

6: A MSIV according to claim 1, wherein in which the metallic layer has a plurality of through-holes defined through the thickness thereof, with internal walls of each of the plurality of through-holes being coated with a portion of the dielectric nanoceramic layer.

7: A MSIV according to claim 1, wherein the through-hole has a diameter of between 20 micrometres and 2000 micrometres.

8: A MSIV according to claim 1, wherein the metallic layer has a plurality of through-holes of between 50 and 200 micrometres in diameter formed through the thickness of the metallic layer, with a spacing between the through-holes being between 50 and 200 micrometres.

9: A MSIV according to claim 1, further comprising at least one more metallic layer, each metallic layer having at least one through-hole with internal walls coated with a dielectric nanoceramic material having properties of the dielectric nanoceramic layer.

10: A MSIV according to claim 1, wherein the MSIV is a flexible electronic substrate (FES) having a minimum bend radius of lower than 25 cm.

11: A MSIV according to claim 1, wherein the metallic layer is formed of a metal selected from a group of metals that includes aluminium, magnesium, titanium, zirconium, tantalum, beryllium, or from an alloy of the group, or from an intermetallic of any of the metals of the group.

12: A MSIV according to claim 1, wherein the MSIV is formed entirely of non-organic materials.

13: A MSIV according to claim 1, wherein the MSIV has a maximum operating temperature in excess of 200° C.

14: A MSIV according to claim 1, wherein the dielectric nanoceramic layer has a dielectric constant of greater than 7.

15: A MSIV according to claim 1, wherein the dielectric nanoceramic layer is formed by electrochemical oxidation of the metallic layer in an alkaline colloidal electrolyte.

16: A MSIV according to claim 1, wherein in which the electrical circuit is formed by one of: a screen printing process, a conductive ink jet printing process, a electroless metallisation process, a galvanic metallisation process, a process that includes adhesive bonding of metal foil, a process that includes bonding of pre-fabricated flex circuits, a metal sputtering process, a chemical vapour deposition (CVD) process, and a physical vapour deposition (PVD) metallisation process.

17: A MSIV according to claim 1, wherein the organic or non-organic material includes a polyimide material, a methacrylate material, an epoxy resin material, an acrylic resin material or a sol-gel material.

18: A method of forming a metal substrate with insulated vias (MSIV) the method, comprising the steps of:
providing a metallic layer;
defining through-holes through a thickness of the metallic layer between a first surface and a second surface of the metallic layer;
forming a dielectric nanoceramic layer on at least one of the first surface and the second surface of the metallic layer and on internal walls of the through-hole, the dielectric layer being formed at least in part by oxidation of the metallic layer;
impregnating at least a portion of the dielectric nanoceramic layer with organic or non-organic material;
filling the through-hole with conductive material to form a conductive via; and
forming an electrical circuit on a portion of the dielectric nanoceramic layer, the electrical circuit being in electrical contact or thermal contact or both electrical and thermal contact with the conductive via,
wherein the dielectric nanoceramic layer has an equiaxed crystalline structure with an average grain size of 500 nanometres or less, a thickness of between 0.1 and 100 micrometres, a dielectric strength of greater than 20 KV mm⁻¹, and a thermal conductivity of greater than 3 W/mK.

19: A method according to claim 18, wherein the dielectric nanoceramic layer is formed by electrochemical oxidation of the metallic layer in an alkaline colloidal electrolyte.

20: A method according to claim 18, wherein the electrical circuit is formed by one of: a screen printing process, a conductive ink jet printing process, a electroless metallisation process, a galvanic metallisation process, a process that includes adhesive bonding of metal foil, a process that includes bonding of pre-fabricated flex circuits, a metal sputtering process, a chemical vapour deposition (CVD) process, and a physical vapour deposition (PVD) metallisation process.

21: A method according to claim 18, wherein the organic or non-organic material includes a polyimide material, a methacrylate material, an epoxy resin material, an acrylic resin material, or a sol-gel material.

22: A MSIV according to claim 1, wherein the MSIV is incorporated as part of a multilayered substrate.

23. A MSIV according to claim 1, wherein the MSIV supports any one or a combination of: an electronic chip or die, an electronic device, a display, a battery, an optoelectronic device, an RF device, a microwave device, a thermoelectric device, and an electrical device.

24: A method according to claim 18, wherein, in the impregnating step, the dielectric nanoceramic layer is impregnated with the organic or non-organic material by one of: a dipping process, a spraying process, a vacuum impregnation process, a chemical vapour deposition (CVD) process, and a physical vapour deposition (PVD) metallisation process.
